(19) United States
(12) Patent Application Publication
(10) Pub. No.: US 2005/0162177 A1
(43) Pub. Date: Jul. 28, 2005

(54) Multi-signal single beam probe

(76) Inventor: Arlen L. Chou, Los Altos, CA (US)

Correspondence Address: MACPHERSON KWOK CHEN & HEID LLP, 1762 TECHNOLOGY DRIVE, SUITE 226, SAN JOSE, CA, 95110, US

(21) Appl. No.: 11/043,630

(22) Filed: Jan. 26, 2005

Related U.S. Application Data
(60) Provisional application No. 60/539,916, filed on Jan. 28, 2004.

(51) Int. Cl. G01R 31/02

(52) U.S. Cl. 324/754

(57) ABSTRACT

Methods and systems are provided for forming multiple electrical connections using a single probe suitable for semiconductor wafer probing and the parametric measurement of micro-devices. A conventional single-beam physical wafer probe structure can support two closely spaced and electrically independent probe contacts if an insulating sheath overlaid by a conducting outside coaxial sheath is used to provide a second independent probe contact.

### CROSS-REFERENCE TO RELATED APPLICATIONS

This application claims the benefit of U.S. Provisional Application No. 60/539,916, filed on Jan. 28, 2004, entitled “Multi-Signal Single Beam Probe,” the disclosure of which is incorporated by reference herein in its entirety.

### BACKGROUND OF THE INVENTION

This application relates generally to the manufacture of a probe for semiconductor wafer probing and the parametric measurement of micro-devices.

Modern semiconductor and other micro-devices are manufactured on wafers of silicon or other suitable material. The key to profit and enhanced device performance is miniaturization. Although wafer sizes can range up to 12 inches or more, each wafer contains a plurality of individual devices, and the structures of each device are minute and growing ever smaller. A complete device having eight contacts may only be 1/100 inch square. Electronic measurements need to be made on these structures. The tiny sizes of the devices require that the contact areas (called pads) available to connect to the devices are correspondingly tiny, to maximize profitability. To contact the pads, physically tiny probes are required.

In the case of pads whose upper surface is a metal which does not easily oxidize (such as gold), probes made of many different materials can be used. When probing a pad with no oxide, the probe can intercept the pad surface vertically or nearly so. Some further mechanical structure associated with the probe provides a spring action.

In the special (but common) case of pads formed of aluminum, the top layer of the pad is always covered by the oxide of aluminum (an insulator), and the probe must always break through this layer in order to make electrical contact with the underlying pad material. It has been learned experimentally that an excellent way of breaking through the oxide is to incline the body of the probe so as to form a “Cantilever Probe”. When such a probe is pressed onto the pad surface, the angle of the cantilever causes the probe tip to break through the oxide at one point, and then “scrub” into the oxide as more pressure is applied, “scrubbing” a short trench. This method penetrates the oxide, allowing the probe to make contact with the aluminum pad beneath, but the motion moves the contact point across the pad from the initial contact point. Accordingly, the pad needs to be large enough to accommodate the added motion. As the devices grow smaller, the pads grow smaller and the contact point motion uses up all the pad width, leaving no allowance for landing point inaccuracy.

The precise measurement of various electronic characteristics of structures present on the wafer substrate are required to monitor the manufacturing process, to decide if a given device is operating within specification, to characterize a new device being developed, etc.

All probe bodies have resistance, and the resistance between the tip of the probe body and the device pad is always uncertain. In particular cases, the required accuracy of the measurements which need to be made will require that methods be used which can make precise measurements in the face of these problems. Generally, a single probe contact will not always make a connection that is certain to be good enough. Parametric measurements made using single probe contact methods are fundamentally inaccurate.

One technique developed to improve the accuracy of parametric measurements is the Kelvin connection system. Kelvin connections reduce or eliminate voltage losses caused by measuring line resistance that would otherwise cause errors in low-voltage measurements. This is accomplished by providing a separate “force” and “sense” line to a measurement point (the Kelvin connection). Current is supplied to the measurement point only through the “force” line. This causes a voltage drop in the “force” line. But the voltage at the measurement point is measured by a high-impedance instrument connected to the measurement point through the “sense” line, drawing no current (incurring no voltage drop in the “sense” line) and therefore making no error.

To use the Kelvin connection system to accurately measure the resistance of some structure between two pads on a wafer requires placing two probes on each of the two pads (four probes total to make only one measurement). To accommodate the placement of two probes on a single pad would require the pads to be made larger than the minimum size required for single probe testing, but economic considerations generally disallow larger or differing pad sizes. Consequently, the two probes assigned to each pad are certain to be almost close enough to touch each other, but they cannot be allowed to. Since each probe introduces its own independent “touchdown point” error, if one probe of the pair is slightly bent, it may be impossible to land them both inside the tiny pad.

Accordingly, there is a need for an improved probe assembly for testing electronic devices.

### SUMMARY OF THE INVENTION

In accordance with the present invention, a single beam probe provides multiple electrical contacts with a test device. This single beam probe may be used to provide both the “force” and the “sense” contacts to a single pad for use in a Kelvin connection system. The two separate probes required for conventional Kelvin connection systems to make independent contact with a tiny pad without simultaneously touching each other can be replaced by a single twin-contact assembly fabricated on a single probe beam.

In accordance with embodiments of the present invention, a probe assembly having two electrically independent contacts can be made by surrounding a core metallic probe (which forms one probe contact having one electrical circuit) with an insulating sheath further surrounded by a conductive sheath which forms a second probe contact having an independent electrical circuit. The two separate probe contacts can be electrically operated in a plurality of modalities, and perform multiple functions.

In accordance with embodiments of the present invention, a probe is provided, comprising: a first conductive element having a distal end and a proximal end; a second conductive element having a distal end and an proximal end; a first dielectric layer provided between the first conductive element and the second conductive element; and a tip having a contact surface comprising the distal end of the first conductive element and the distal end of the second conductive element.

In accordance with embodiments of the present invention, a method of forming a probe is provided, comprising: providing a first conductive probe element; coating the first conductive probe element with a first dielectric layer; coating the first dielectric layer with a second conductive probe element.

In accordance with embodiments of the present invention, a method of testing a device is provided, comprising: contacting a contact pad with a probe comprising an inner conductive element and an outer conductive element coaxial with the inner conductive element and separated from the inner conductive element with a dielectric sleeve; supplying a current to the contact pad using one of the inner conductive element or the outer conductive element; and measuring a voltage at the contact pad using the other of the inner conductive element or the outer conductive element.

In accordance with embodiments of the present invention, a dual contact probe is provided, comprising: a conducting needle; a first dielectric sheath surrounding the conducting needle; a conductive sheath surrounding the first dielectric sheath; a first electrical connection to the conducting needle; and a second electrical connection to the conductive sheath separate from the first electrical connection.

Other features and aspects of the invention will become apparent from the following detailed description, taken in conjunction with the accompanying drawings which illustrate, by way of example, the features in accordance with embodiments of the invention. The summary is not intended to limit the scope of the invention, which is defined solely by the claims attached hereto.

### DESCRIPTION OF THE DRAWINGS

FIG. 1 shows a probe test assembly which can be used to test an electronic device, in accordance with embodiments of the present invention.

FIG. 2A shows an un-bent probe needle use, in accordance with embodiments of the present invention.

FIG. 2B shows a bent probe needle used, in accordance with embodiments of the present invention.

FIG. 3 shows a bent probe needle (in cantilever configuration) with an insulating sheath applied, in accordance with embodiments of the present invention.

FIG. 4 shows the probe assembly of FIG. 3 with outer conducting layer(s) applied and further outer protective and insulating layer(s) applied, in accordance with embodiments of the present invention.

FIG. 5 shows the probe assembly of FIG. 3 with probe contact surface shaping, in accordance with embodiments of the present invention.

FIG. 6A shows the probe assembly of FIG. 4 with contact surface shaping, in accordance with embodiments of the present invention.

FIG. 6B shows the probe contact surface footprint of the probe assembly of FIG. 6A, in accordance with embodiments of the present invention.

### DETAILED DESCRIPTION

In the following description, reference is made to the accompanying drawings which illustrate several embodiments of the present invention. It is understood that other embodiments may be utilized and mechanical, compositional, structural, electrical, and operational changes may be made without departing from the spirit and scope of the present disclosure. The following description is meant to be illustrative only and not limiting. Other embodiments of this invention will be obvious from this description to those skilled in the art.

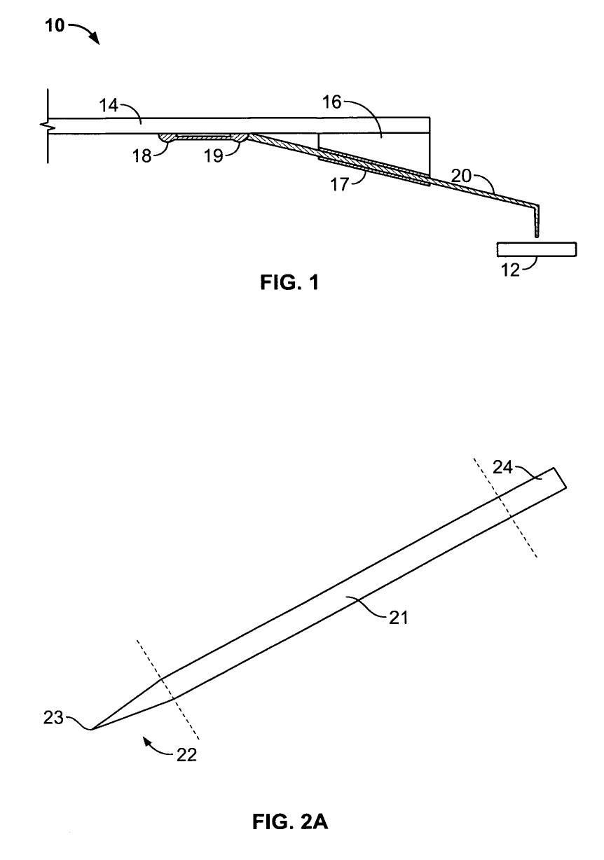

FIG. 1 shows a probe test assembly 10 which can be used to test an electronic device 12 having a plurality of contact pads provided thereon, in accordance with embodiments of the present invention. Each of these contact pads are metallized locations on the integrated circuit being tested. The probe test assembly 10 comprises a probe substrate 14, which may comprise a printed circuit board (“PCB”) and a stiffening substrate. A ring 16 is mounted to the probe substrate. A plurality of probes 20 are mounted to the ring 16 using, e.g., epoxy 17. In the illustrated embodiment, each probe 20 has two electrical connections to the substrate 14, inner signal solder contact point 18 and outer signal solder contact point 19, as will be described in greater detail below.

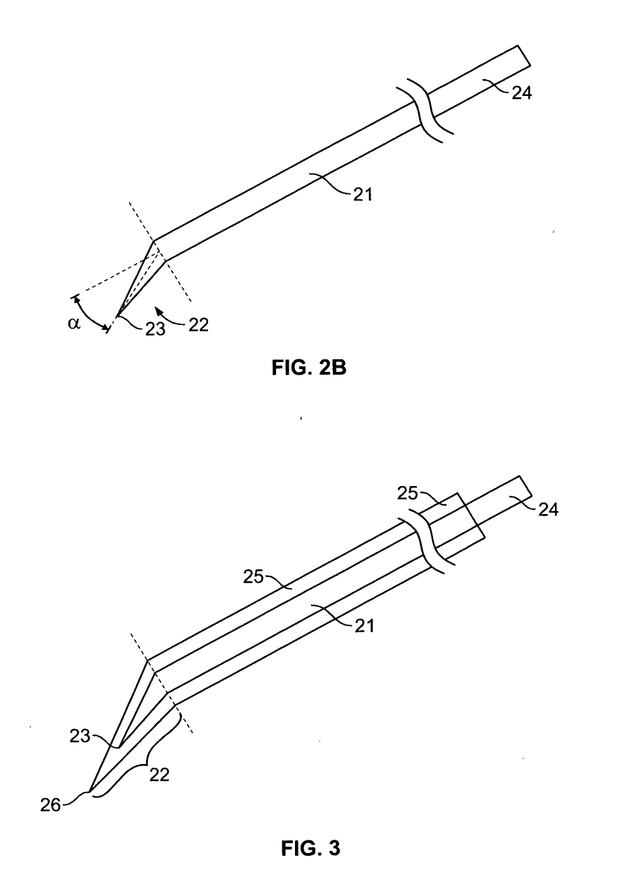

FIG. 2A shows a first conductive element 21 for a probe 20 in accordance with embodiments of the present invention. The first conductive element 21 comprises a metal needle which includes a proximal end forming a mounting end 24 for attaching the probe 20 to the blade 16 and a distal tapered end 22 terminating at a probe tip 23. The probe tip 23 contacts the contact pad on the test device 12.

The needle forming the first conductive element 21 may take various forms and sizes, depending on the desired application. Suitable needles are manufactured and sold as semiconductor probe needles by various companies, including, e.g., Point Technologies, Inc., of Boulder, Colo., and Advanced Probing Systems, Inc., of Boulder, Colo. The material forming the needle may vary, depending on the application and the desired mechanical and electrical characteristics. For example, the needle may be a pure element such as tungsten, or an alloy of elements such as gold, platinum, palladium, silver, copper, beryllium, etc. Some common alloys include tungsten-rhenium, beryllium-copper, and various alloys of palladium, gold, platinum, silver, copper, and zinc. The needle may also be plated with a material chosen for its enhanced solderability, such as rhodium, gold, nickel, or silver, especially at the mounting end 24. The taper of the probe tip 23 may be formed using a variety of methods known to those of ordinary skill in the art, such as grinding, electrochemical machining, and forming.

In some embodiments, it is desirable for tip of the probe 20 to be bent at an angle to the axis of the main shaft forming the probe 20. In the embodiment shown in FIG. 2B, the tip 23- of the needle is mechanically bent at an angle a to the axis of the main shaft prior to the formation of layers over the needle 21, as described in greater below. By bending the needle prior to subsequent manufacturing steps, the amount of stress applied to the outer layers of the probe 20 can be decreased. However, in other embodiments, the probe 20 can be bent after some or all of the additional layers are applied.

In FIG. 3, a layer 25 of a dielectric material is applied to the needle 21. This layer 25 forms an insulating sheath over the needle 21. In a later production step, the insulating material will be removed from the probe tip region 26 in order to expose the tip 23 of the needle so that the needle can make electrical contact with the pad of the electronic device 12 being tested. The dielectric material may comprise, e.g., an epoxy, plastic, polyamide, or the like. More than one layer of insulating material may be applied in order to achieve better electrical or mechanical performance. The dielectric layer 25 may be applied using a variety of techniques, depending on the composition of the needle and the dielectric layer 25 and other considerations (e.g., uniformity of dielectric layer thickness, cost, speed of manufacturing, etc.), and may include, e.g., dipping and chemical vapor deposition.

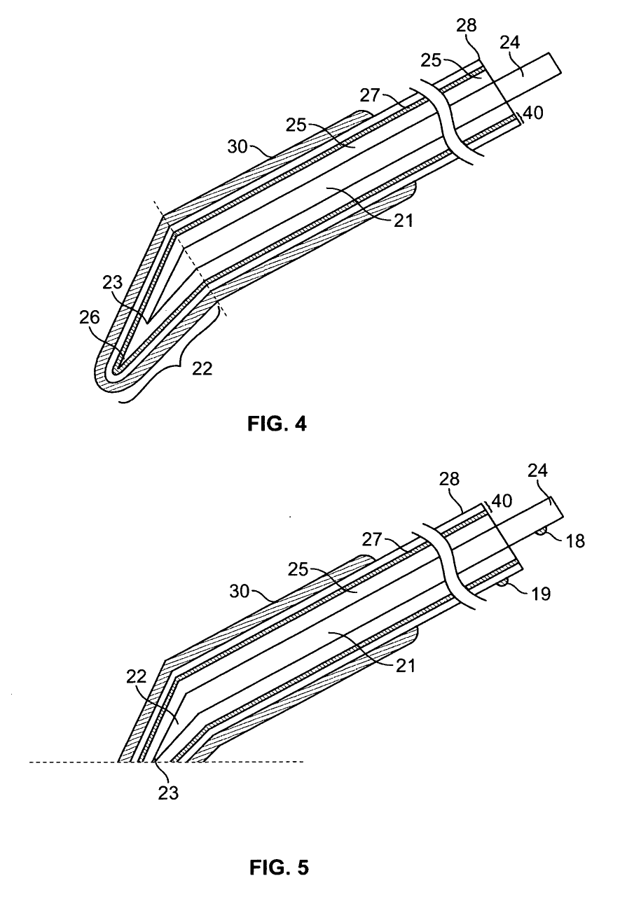

Next, as shown in FIG. 4, a second conductive element 40 is applied over the dielectric layer 25. This second conductive element 40 may comprise one or more electrically conductive layers (shown in FIG. 4 as layers 27 and 28) that substantially surround the dielectric layer 25. The layer(s) 27 and 28 may form a complete cylinder (radially) or a partial cylinder.

In the embodiment shown in FIG. 4, the layer 27 comprises a primer layer 27 of an electrically-conductive metallic-embedded polymer. The primer layer 27 may comprise, e.g., epoxy, plastic, polyamide or the like, with a metal or metal alloy embedded therein to provide electrical conductivity. Depending on the content of the conductive material in the primer layer 27, the primer layer 27 may have varying conductive qualities. In some embodiments, where the metallic content is high, the primer layer 27 may be sufficiently conductive to carry a signal from the distal end of the probe to the proximal end. In other embodiments, where the metallic content is low, the primer layer 27 may carry only a residual signal. The primer layer may be applied using various techniques known in the art, such as dipping and chemical vapor deposition. The second conductive layer 28 may comprise, e.g., a metal layer such as nickel, gold, or copper over the underlying primer layer 27.

In other embodiments, the second conductive element 40 may be formed by the primer layer 27 alone or the second conductive layer 28 alone. If the second conductive layer 28 is applied over the primer layer 27, it will act to lower the total effective electronic resistance of the second conductive element 40. The primer layer 27 may provide improved adhesion to the underlying dielectric layer 25.

One or more additional protective and insulating layers 30 may be applied to the outer surface of the assembly. The protective layer 30 may comprise, e.g., a layer of epoxy, plastic, polyamide or the like which can simultaneously serve to protect the second conductive element 40 from damage and to prevent accidental electronic contact between the second conductive element 40 and any other conductor, such as another probe assembly or a foreign body introduced into the probe tip area.

Two electrical connections 18-19 are made to the probe 20. The first electrical connection 18 may be made to the exposed mounting end 24 of the first conductive element 21 and second electrical connection 19 is made to the second conductive element 40 (e.g., either to the primer layer 27 or the second conductive layer 28). It may be desirable to remove a portion of the protective layer 30 in order to expose the second conductive element 40 for making the second electrical connection 19. Similarly, a portion of the second conductive element 40 and the dielectric layer 25 may be removed to expose the first conductive element (i.e., metal needle 21) for making the first electrical connection 18. The two electrical connections 18-19 may e.g., take the form solder contacts with conductive traces on the substrate 14, or may take the form of wires connected to the probe 20.

Accordingly, this arrangement provides a probe 20 having two independent electrical circuits that contact the wafer surface, each of which separately leads to an electrical path to an electronic test system. Because the two conductive elements are provided on a single member (the probe 20) but are electrically isolated, the probe 20 may be used to perform parametric measurements (such as Kevin connection measurements) on very small contact regions.

As shown in FIG. 5, the surface of the second conductive element 40 which will contact the pad or wafer surface may be given a particular shape designed to achieve a particular objective. Since there are several possible different applications of the present invention, there are several possible different shapes.

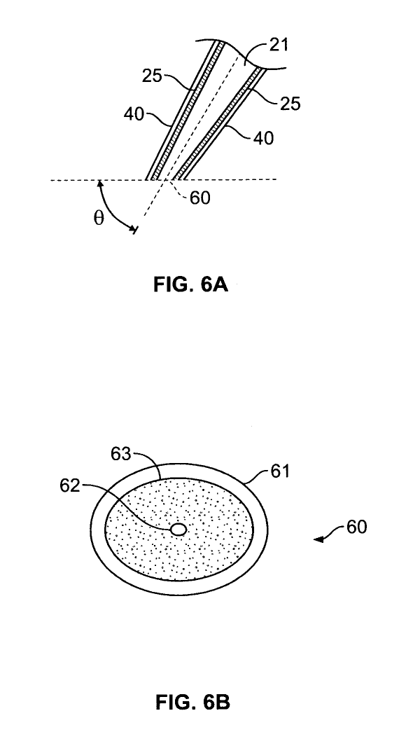

In one embodiment shown in FIG. 6A, the tip of the probe assembly beveled to provide a flat contact surface 60 (shown in FIG. 6B) at an angle θ to the axis of the probe tip. The bevel may be formed using a variety of methods, such as, e.g., grinding or polishing. After shaping, it may be desirable to reduce the roughness of the contact surface 60 of the probe 20 by polishing either electro-chemically or mechanically. In operation, this contact surface 60 is positioned against the contact pad of the device being tested.

As shown in FIG. 6B, the resulting contact surface 60 comprises an oval contact ring 61 surrounding a small oval contact point 62. The oval contact ring 61 (which corresponds to the distal end of the first conductive element 21) is separated from the oval contact point 62 (which corresponds to the distal end of the second conductive element 40) by an oval dielectric ring 63 (which corresponds to the dielectric layer 25). In operation, this contact surface 60 may be placed in contact with a pad on the electric device 12 being tested in order to provide two separate electrical circuits with the pad. In some embodiments, the oval contact point 62 may have a surface area ranging from approximately 0.25 mils to approximately 1.5 mils, the oval contact ring 61 may have a thickness ranging from approximately 0.1 mil to approximately 1 mil, and the oval dielectric ring 63 may have a thickness ranging from approximately 0.1 mil to approximately 1.5 mils. In other embodiments, the dimensions of the various components may vary. In addition, depending on the techniques use to manufacture the probe, the dimensions of the layers may vary in size and uniformity.

In accordance with an embodiment of the present invention, a probe 20 may be used for performing Kelvin connection measurements. When operating a Kelvin connection system, two connections are made to a single electrical contact on a test device 12. One of the connections comprises a lower resistance “force” line, and the other connection forms a higher resistance “sense” line. In the case that the outer coaxial conductive element 40 provides a lower resistance than the inner conductive element 21, the outer conductive element 40 would provide the “force” line and the inner conductive element 21 would provide the “sense” line. In the case that the outer coaxial conductive element 40 provides a higher resistance than the inner conductive element 21, the outer conductive element 40 would provide the “sense” line and the inner conductive element 21 would provide the “force” line.

When operating as a conventional passive shield system, the outer conductive layer(s) would provide a passive shield, and the inner probe would provide the shielded “force” or “sense” line. When operating as an active or driven shield system, the outer conductive layer(s) would provide an active or driven shield, and the inner probe would provide the “sense” line.

In yet another embodiment, a third conductive element may be provided. The third conductive element may be coaxial with and surround the first and second conductive elements 21, 40. This third conductive element may provide a shielding layer, while the first and second conductive elements 21, 40 operate as the “force” and “sense” lines.

Due to the proximity of the “force” and “sense” contact points at the contact surface of the probe, the probe has an increased susceptibility to accidental shorting of the contact points caused by contaminants on the tip of the probe. Accordingly, it is desirable to maintain a regular cleaning cycle during usage.

In one embodiment, it is envisioned to exploit the inherent or enhanced flexibility of the primer layer 27 to provide a built-in spring action similar to a pogo-pin. In vertical probing, the flexibility of the primer layer 27 could provide a large contact area if the primer layer 27 were extended beyond the probe tip and contacted an extended area on the object being probed.

In the various embodiments described above, the probes may be suitable for use in testing electronic devices. These probes may have a final diameter ranging from approximately 6 mils to approximately 14 mils, with a contact surface on the probe tip having an area of approximately 1 mil² to approximately 4 mil². Certain embodiments may have particular applicability for testing read/write heads for hard disk drives. These read/write heads may have contact pads having a surface area of approximately 2 mil² to approximately 4 mil². In order to test these read/write heads using the Kelvin connection system, it is desirable for the probe tip to have a contact surface area as small as possible to fit within the die pad area.

While the invention has been described in terms of particular embodiments and illustrative figures, those of ordinary skill in the art will recognize that the invention is not limited to the embodiments or figures described. For example, in the embodiments described above, the probe 20 has a bent tip, suitable for use in a cantilever-type probe test assembly 10. In other embodiments, the probe 20 may be straight or have different shapes, such as curved or rounded.

The figures provided are merely representational and may not be drawn to scale. Certain proportions thereof may be exaggerated, while others may be minimized. The figures are intended to illustrate various implementations of the invention that can be understood and appropriately carried out by those of ordinary skill in the art.

Therefore, it should be understood that the invention can be practiced with modification and alteration within the spirit and scope of the appended claims. The description is not intended to be exhaustive or to limit the invention to the precise form disclosed. It should be understood that the invention can be practiced with modification and alteration and that the invention be limited only by the claims and the equivalents thereof.

1. A probe, comprising:
a first conductive element having a distal end and a proximal end;
a second conductive element having a distal end and an proximal end;
a first dielectric layer provided between the first conductive element and the second conductive element; and
a tip having a contact surface comprising the distal end of the first conductive element and the distal end of the second conductive element.

2. The probe of claim 1, wherein the second conductive element is substantially tubular and the first conductive element is provided within the second conductive element.

3. The probe of claim 1, wherein the first conductive element and second conductive element comprise gold, platinum, palladium, silver, copper, beryllium, tungsten, tungsten-rhenium, beryllium-copper, or zinc.

4. The probe of claim 1, wherein the second conductive element comprises a primer layer comprising a dielectric material embedded with a conductive material.

5. The probe of claim 4, wherein the dielectric material comprises a polymer embedded with a metal.

6. The probe of claim 4, wherein the second conductive element further comprises a conductive layer, wherein the primer layer is disposed between the conductive layer and the first conductive element.

7. The probe of claim 1, wherein the first dielectric layer comprises an epoxy, plastic, or polyamide.

8. The probe of claim 1, further comprising a second dielectric layer surrounding the second conductive element.

9. The probe of claim 1, wherein the contact surface has an area of less than 4 mil².

10. The probe of claim 1, wherein the probe has a shaft diameter of less than 14 mil.

11. The probe of claim 1, further comprising a plurality of coaxial conductive layers, each conductive layer being separated from adjacent conductive layers by dielectric layers.

12. The probe of claim 1, wherein at the contact surface, the distal end of the first conductive element is separated from the distal end of the second conductive element by a distance less than 1.5 mil.

13. A method of forming a probe, comprising:
providing a first conductive probe element;
coating the first conductive probe element with a first dielectric layer;
coating the first dielectric layer with a second conductive probe element.

14. The method of claim 13, wherein the first conductive probe element comprises a probe needle having a diameter of less than 10 mils.

15. The method of claim 13, wherein the first conductive element and second conductive element comprise gold, platinum, palladium, silver, copper, beryllium, tungsten, tungsten-rhenium, beryllium-copper, or zinc.

16. The method of claim 13, wherein:
the first dielectric layer comprises a polymer; and
said coating the first dielectric layer with the second conductive probe element comprises coating the first dielectric layer with a primer layer comprising a polymer-metal compound.

17. The method of claim 16, wherein:
said coating the first dielectric layer with the second conductive probe element further comprises coating the primer layer with a metallic layer.

18. The method of claim 13, wherein said coating the first conductive probe element with a first dielectric layer comprises dipping the first conductive probe element into a molten dielectric material to form the first dielectric layer on the first conductive probe element.

19. The method of claim 13, wherein said coating the first conductive probe element with a first dielectric layer comprises applying a dielectric material using vapor deposition to form the first dielectric layer on the first conductive probe element.

20. The method of claim 13, further comprising:
forming a contact surface at a distal end of the probe, the contact surface comprising a distal end of the first conductive probe element and a distal end of the second conductive probe element.

21. The method of claim 20, wherein the contact surface has an area of less than 4 mil².

22. The method of claim 20, wherein at the contact surface, the distal end of the first conductive probe element is separated from the distal end of the second conductive probe element by a distance less than 1.5 mil.

23. The method of claim 13, wherein the probe has a shaft diameter of less than 14 mil.

24. The method of claim 13, further comprising applying a plurality of coaxial conductive layers, each conductive layer being separated from adjacent conductive layers by dielectric layers.

25. A method of testing a device, comprising:
contacting a contact pad with a probe comprising an inner conductive element and an outer conductive element coaxial with the inner conductive element and separated from the inner conductive element with a dielectric sleeve;
supplying a current to the contact pad using one of the inner conductive element or the outer conductive element; and
measuring a voltage at the contact pad using the other of the inner conductive element or the outer conductive element.

26. The method of claim 25, wherein the second conductive element is substantially tubular and the inner conductive element comprises a probe needle provided within the outer conductive element.

27. The method of claim 25, wherein the outer conductive element comprises a primer layer comprising a dielectric material embedded with a conductive material.

28. The probe of claim 27, wherein the dielectric material comprises a polymer embedded with a metal.

29. The method of claim 27, wherein the outer conductive element further comprises a conductive layer, wherein the primer layer is disposed between the conductive layer and the inner conductive element.

30. The method of claim 25, wherein the probe further comprises an outer dielectric layer surrounding the outer conductive element.

31. The method of claim 25, wherein the probe contacts the contact pad with a contact surface having an area of less than 4 mil².

32. The method of claim 25, wherein the probe has a shaft diameter of less than 14 mil.

33. A dual contact probe, comprising:
a conducting needle;
a first dielectric sheath surrounding the conducting needle;
a conductive sheath surrounding the first dielectric sheath;
a first electrical connection to the conducting needle; and
a second electrical connection to the conductive sheath separate from the first electrical connection.

34. The dual contact probe of claim 33, wherein the conductive sheath comprises a layer of epoxy, plastic, or polymer containing a sufficient amount of conductive material to render the conductive sheath electrically conductive.

35. The dual contact probe of claim 34, wherein the conductive sheath further comprises a layer of conductive material surrounding the layer of epoxy, plastic, or polymer.

36. The dual contact probe of claim 33, further comprising a second dielectric sheath surround the conductive sheath.

37. The dual contact probe of claim 33, further comprising a planar contact area at a distal end of the probe, the planar contact area forming an oblique angle with an axis of the conducting needle.
